(19) United States
(12) Patent Application Publication
(10) Pub. No.: US 2002/0105375 A1
(43) Pub. Date: Aug. 8, 2002

(54) Method and apparatus for detecting finger merge condition in CDMA receiver

(76) Inventor: Vladislav Sorokine, San Diego, CA (US)

Correspondence Address: QUALCOMM Incorporated, 5775 Morehouse Drive, San Diego, CA, 92121-1714, US

(21) Appl. No.: 09/961,226

(22) Filed: Sep. 20, 2001

Related U.S. Application Data
(60) Provisional application No. 60/234,316, filed on Sep. 20, 2000.

(51) Int. Cl. H03L 7/00; H03D 3/00

(52) U.S. Cl. 329/345

(57) ABSTRACT

Techniques are described whereby noise estimates from individual finger processors are compared using a noise estimator, and a finger merge condition declared on the basis of such comparison. In one embodiment, when noise estimates from two or more finger processors is identical or nearly identical, finger merge is presumed such that noise estimates from merged fingers are blocked from forming a combined noise estimate. Furthermore, in another scheme a correcting factor is introduced to account for the correlation between noise samples from merged fingers. In a further embodiment, a computationally effective procedure to perform comparisons between the noise estimates from individual fingers is implemented by sorting noise estimates according to respective magnitudes to create a sort list. In one implementation, only samples that are neighbors in the sorted list are then compared. The techniques described may be implemented to mitigate the problem of noise under-estimation in a finger merge condition, particularly as relates in the context of signal quality estimation for purposes of fast forward power control.

### CROSS-REFERENCE TO RELATED APPLICATIONS

This application claims the benefit of U.S. Provisional Patent Application No. 60/234,316, entitled “A Method for Detection of a Finger Merge Condition in CDMA Receivers,” filed Sep. 20, 2000.

### BACKGROUND

1. Field

The present invention relates generally to data communication, and more specifically to techniques for detecting a finger merge condition in a CDMA receiver.

2. Background

Wireless communication systems are widely deployed to provide various types of communication such as voice, packet data, and so on. These systems may be based on code division multiple access (CDMA), time division multiple access (TDMA), or some other modulation techniques. CDMA systems may provide certain advantages over other types of system, including increased system capacity.

For many wireless communication systems, a pilot is transmitted along with signaling and traffic data (e.g., voice and/or packet data) from a transmitter unit to a receiver unit. The pilot is typically a known data pattern that is processed and modulated in a known manner. Signaling and traffic data are also processed and modulated via respective schemes, combined with the processed pilot, and transmitted from a base station (BS) to a mobile station (MS). The transmitted pilot allows the receiver unit to estimate the communication link used to transmit signaling and traffic data.

At the MS, a rake receiver is often used to recover the transmitted pilot, signaling, and traffic data. The transmitted signal may be received via multiple signal paths (or multipaths). Each received multipath is typically assigned a respective finger processor of the rake receiver. The finger processors process the pilot in a complementary manner to derive a pilot reference having amplitude and phase determined by the characteristics of that multipath.

The pilot reference is typically used to coherently demodulate the signaling and traffic data, which are transmitted along with the pilot and are similarly distorted by the propagation path. In addition, the pilot references for the received multipaths are used to combine the demodulated multipaths to derive an improved estimate of the transmitted signaling and traffic data.

The assignment of paths to respective finger processors is performed cyclically. Between processing cycles of finger assignments, another mechanism, generally known as a time-tracking loop, maintains finger lock on a particular path.

Higher level software avoids assigning two or more finger processors to the same path during an assignment cycle. However, it remains possible that between assignment cycles the time-tracking loop may move a finger processor to the same path as that already assigned to a different finger processor.

Thus, between assignment cycles, two or more finger processors may track the same path, at least temporarily. Two or more fingers tracking the same path is a condition known as finger merge. This condition may occur, for example, when two finger processors assigned to two distinct components of a multipath are temporally close to each other. This condition is illustrated in FIG. 1, which shows what may occur, between the finger assignment cycles, where one path temporally close to a strong path becomes very weak.

In the illustrative example, the time-tracking loop moves its assigned finger to the neighboring stronger path. (During the next assignment cycle, finger merge is not a problem; once detected, the higher level software re-assigns one of the fingers in a known manner.)

In general, when two finger processors are assigned a multipath one or more pseudo-random number (PN) chips apart, the noise components of the finger processors are said to be un-correlated. As two finger processors start to timetrack toward each other, the noise component seen by each finger processor becomes less un-correlated. At a point in time (between assignment cycles) when the finger processors timetrack to the same PN offset, a finger merge results, and the noise components become 100% correlated.

Another mechanism, generally known as a noise estimator, assumes that the noise components of each finger are uncorrelated. The total noise components from the two finger processors is the sum of the noise component from each finger processor. In order to obtain an overall noise estimate, the noise estimator simply adds each noise component contributed by each finger, as shown in FIG. 2. In the event two fingers merge, at which point the noise components are 100% correlated, the noise estimator underestimates the combined noise contribution due to this nonzero cross-correlation between finger processors. In the case of a two-finger merge, the noise estimator will under-estimate the true (combined) noise interference level by a factor of 2.

Undestimation may have potentially harmful effects on the operation of the inner loop of the power control algorithm. In particular, an underestimation of the noise interference level by, for example, a factor of 2 results in an overestimation of the true signal-to-noise interference ratio (Eb/Nt) by a similar factor of 2, or 3 dB (for the case of two branches in FIG. 2).

Fast forward power control, in particular, requires that the MS determine noise estimates accurately. An ovestimation may, in the case of fast forward power control, negatively affect fast forward power control efficiency. A sudden overestimation of Eb/Nt may cause the MS to send a stream of down command request to the BS, instructing the BS to reduce its transmit power. Because of finger-merge associated overstimation (and incident incorrect formation of the Eb/Nt estimate), the MS requests the BS to reduce transmit power in some cases to a level so low as to cause frame erasures. The outer loop of the power control algorithm, in turn, causes the BS to turn up the power level to correct for what it believes to be an unacceptable degree of erasures. When the number of the erasures caused by the incorrect Eb/Nt estimate are excessive, the outer loop power control converges to a level that is not optimal or, alternatively, does not converge at all.

Detecting finger merge between assignment cycles, by employing higher-level software to detect and correct, imposes high computational costs on the MS, and is also difficult to implement.

A simple solution to mitigate the problem of noise under-estimation in a finger merge condition is desirable.

### SUMMARY

Aspects of the invention provide techniques for detecting a finger merge condition to mitigate the adverse affects of incorrect information regarding detected noise estimates.

A technique is described whereby noise estimates from individual finger processors are compared using a noise estimator, and a finger merge condition declared on the basis of such comparison.

In one embodiment, when noise estimates from two or more finger processors is identical or nearly identical, finger merge is presumed such that noise estimates from merged fingers are blocked from forming a combined noise estimate. Furthermore, in another scheme a correcting factor is introduced to account for the correlation between noise samples from merged fingers.

In a further embodiment, a computationally effective procedure to perform comparisons between the noise estimates from individual fingers is implemented by sorting noise estimates according to respective magnitudes to create a sort list. In one implementation, only samples that are neighbors in the sorted list are then compared.

Furthermore, any such sorting may be performed only from time to time, while at other times only checking that fingers remain sorted, is required.

In a further embodiment, because of correlations between consecutive noise estimates, the noise estimator checks whether the fingers are sorted, and when not sorted, determines a “dis-sorting” distance, i.e., estimates the degree to which fingers have become un-sorted.

It a yet further embodiment, noise estimator efficiency is improved by coordinating pre-sorting operation with finger assignment timing. This way, control over maintaining fingers in a sorted order (and taking an appropriate corrective action in the case of merged fingers) between the assignment cycles is passed to a lower level sorting/correcting algorithm as part of the noise estimator operation.

Various approximations are described for computations of appropriate parameters and other threshold values implemented by the noise estimator in detecting a finger merge condition. For example, in a two-finger merge scenario, the noise estimator may under-estimate the combined noise estimate of merged fingers by a correcting factor of two (2).

The techniques described may be implemented to mitigate the problem of noise under-estimation in a finger merge condition, particularly as relates in the context of signal quality estimation for purposes of fast forward power control.

The techniques described herein may be used for any communication system in which pilot and non-pilot symbols are transmitted (e.g., in a time-division multiplexed manner) and may be advantageously used in various CDMA systems (e.g., a cdma2000 system, a W-CDMA system, and others).

The invention further provides other methods, apparatus, and elements that implement various aspects, embodiments, and features of the invention, as described in further detail below.

### BRIEF DESCRIPTION OF THE DRAWINGS

The features, nature, and advantages of the present invention will become more apparent from the detailed description set forth below when taken in conjunction with the drawings in which like reference characters identify correspondingly throughout and wherein:

FIG. 1 illustrates a finger merge condition;

FIG. 2 is a simplified block diagram of a conventional rake receiver noise estimator architecture;

FIG. 3 is a diagram of a wireless communication system that supports a number of users and capable of implementing various aspects of the invention;

FIG. 4 is a general flow diagram of the processing for a forward link transmission from a base station to a remote terminal;

FIG. 5 is a detailed block diagram of one embodiment of a rake receiver including a noise estimator capable of implementing various aspects of the invention;

FIG. 6 shows noise estimation comparison operation during fast forward power control;

FIG. 7 is a simplified block diagram and operational flow diagram of one embodiment of a noise estimator architecture in accordance with the invention showing a comparison of noise estimates;

FIG. 8 is a simplified block diagram and operational flow diagram of a first implementation of a noise estimator architecture when the comparison in FIG. 7 suggests a finger merge condition has occurred; and

FIG. 9 is a simplified block diagram and operational flow diagram of an alternate implementation of a noise estimator architecture showing a different solution when a finger merge condition has occurred.

### DETAILED DESCRIPTION

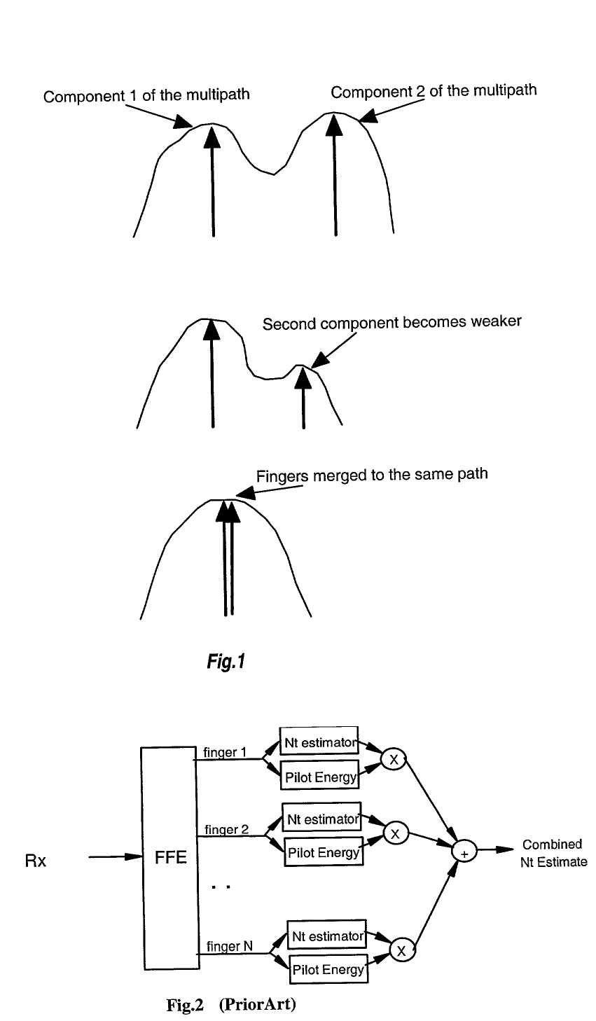

FIG. 1 is a diagram of a wireless communication system 100 that supports a number of users and capable of implementing various aspects of the invention. System 100 provides communication for a number of cells, with each cell being serviced by a corresponding base station transceiver 104. Various remote terminals 106 are dispersed throughout the system. Each remote terminal 106 may communicate with one or more base stations 104 on the forward and reverse link at any particular moment, depending on whether or not the remote terminal is active and whether or not it is in soft handoff. The remote terminals are also commonly referred to as mobile stations (MS). The forward (i.e., downlink) refers to transmission from base station 104 to remote terminal 106, and the reverse link (i.e., uplink) refers to transmission from remote terminal 106 to base station 104.

As shown in FIG. 3, base station 104a communicates with remote terminals 106a, 106b, 106c, and 106d, and base station 104b communicates with remote terminals 106d, 106e, and 106f. Remote terminal 106d, for illustration purposes, is in soft handoff and concurrently communicates with base stations 104a and 104b.

In system 100, a base station controller (BSC) 102 couples to base stations (BS) 104 and may further couple to a public switched telephone network (PSTN) via a mobile switching center (MSC), which is not shown in FIG. 3 for simplicity. The BSC may also couple into a packet network via a packet data serving node (PDSN), which is also not shown in FIG. 1. BSC 102 provides coordination and control for the base stations coupled to it. BSC 102 further controls the routing of telephone calls among remote terminals 106, and between remote terminals 106 and users coupled to the PSTN (e.g., conventional telephones) and to the packet network, via base stations 104.

The system 100 can be designed to support one or more CDMA standards such as the IS-95, IS-98, cdma2000, W-CDMA, some other CDMA standard, or a combination thereof. These CDMA standards are known in the art and incorporated herein by reference.

Various aspects and embodiments of the invention can be applied to both the forward and reverse link in a wireless communication system, as should be made further clear below.

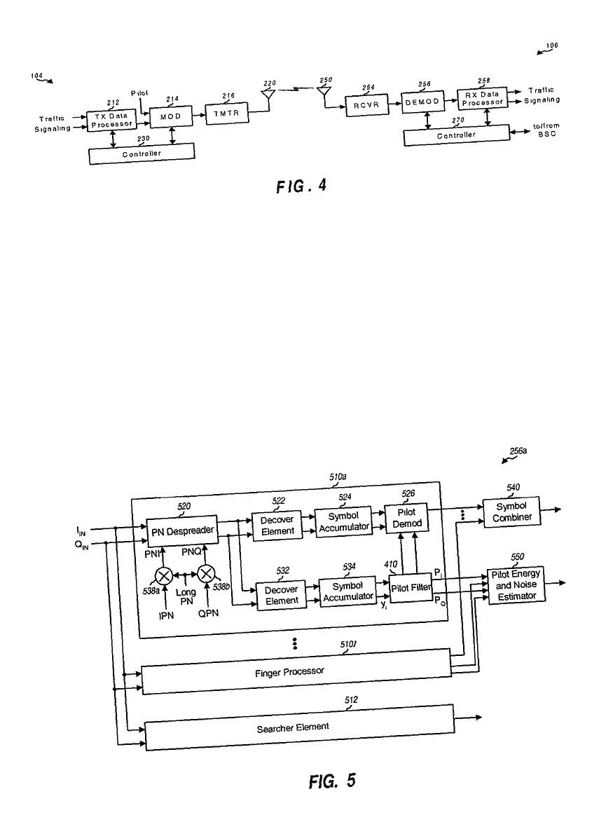

FIG. 4 is a simplified block diagram of the processing for a forward link transmission from base station 104 to remote terminal 106. At base station 104, voice and/or packet data (i.e., traffic data) and control data (i.e., signaling) are provided to a transmit (TX) data processor 212, which formats and encodes the data with one or more coding schemes to generate coded data. Each coding scheme may include any combination of cyclic redundancy check (CRC), convolutional, Turbo, block, and other coding, or no coding at all. Voice, packet, and control data are typically coded using different schemes, and different types of control data may also be coded differently.

The coded data is then provided to a modulator (MOD) 214 and further processed (e.g., covered, spread with short PN sequences, and scrambled with a long PN sequence assigned to the user terminal) to generate modulated data. Pilot data is also typically processed in accordance with another scheme to provide modulated pilot. The modulated data and pilot are combined and provided to a transmitter unit (TMTR) 216 and conditioned (e.g., converted to one or more analog signals, amplified, filtered, and quadrature modulated) to generate a forward link signal that is transmitted via an antenna 220 to remote terminal 106.

At remote terminal 106, the forward link signal is received by an antenna 250 and provided to a receiver unit (RCVR) 254. Receiver unit 254 conditions (e.g., filters, amplifies, downconverts, and digitizes) the received signal and provides samples. A demodulator (DEMOD) 256 receives and processes (e.g., despreads, decovers, and pilot demodulates) the samples to provide recovered symbols. Demodulator 256, in accordance with an aspect of an embodiment of the present invention, implements a rake receiver that processes multiple instances of the received signal and generates combined symbols. A receive (RX) data processor 258 then decodes the symbols to recover the traffic data and signaling that were transmitted on the forward link. The processing by demodulator 256 and RX data processor 258 may be complementary to that performed at base station 104. Demodulator 256 operation will be described in further detail below.

For some wireless systems, a pilot is transmitted along with signaling and traffic data from the base station to the remote terminals, and vice versa. The transmitted pilot is used by the receiving unit to coherently demodulate signaling and traffic data transmitted along with the pilot.

The received signal may be processed and digitized to provide (complex-value) samples. The samples corresponding to each received multipath may be processed by an assigned finger processor of the rake receiver 256.

FIG. 5 is a block diagram of an exemplary embodiment of a rake receiver 256a, and which is a specific design for demodulator 256 in FIG. 4, in accordance with an aspect of the present invention. A skilled artisan should appreciate, however, that the invention is equally applicable to various rake receiver design variations known in the art in which the invention as described below may be implemented.

Rake receiver 256a is capable of implementing various aspects of the invention. Due to multipath and other phenomena, a transmitted signal may reach the base station via multiple signal paths. For improved performance, rake receiver 256a is designed with the capability to process multiple (and typically strongest) instances of the received signal (or multipaths). Rake receiver 256a includes a number of finger processors 510, with each finger processor 510 comprising a finger of the rake receiver and can be assigned to process a particular multipath.

As shown in FIG. 5, the complex samples, I_{IN} and Q_{IN}, from receiver 254 are provided to a number of finger processors 510a through 510l. Within each assigned finger processor 510, the I_{IN} and Q_{IN} samples are provided to a PN despreader 520, which also receives a complex PN sequence, PNI and PNQ. The complex PN sequence is generated in accordance with the particular design of the CDMA system being implemented and, which differ between CDMA200 and WCMDA systems for example.

In the illustrative embodiment, the complex PN sequence is generated by multiplying the short IPN and QPN sequences with the long PN sequence by multipliers 538a and 538b. The PNI and PNQ sequences are generated with a time offset corresponding to that of the multipath being processed by that finger processor.

PN despreader 520 performs a complex multiply of the complex I_{IN} and Q_{IN} samples with the complex PN sequence and provides complex despread I_{DES} and Q_{DES} samples to decover elements 522 and 532. Decover element 522 decovers the despread samples with one or more channelization codes (e.g., Walsh codes) that were used to cover the data and generates complex decovered samples. The decovered samples are then provided to a symbol accumulator 524 that accumulates the samples over the length of the channelization code to generate decovered symbols. The decovered symbols are then provided to a pilot demodulator 526.

A pilot signal is transmitted on the forward link transmission. Decover element 532 decovers the despread samples with the particular channelization code (e.g., a Walsh code 0 for some CDMA systems, or an OVSF code of 0 for a W-CDMA system) that was used to cover the pilot at the base station. The decovered pilot samples are then provided to an accumulator 534 and accumulated over a particular time interval to generate samples yᵢ, for i=1, . . . , N_{P}, corresponding to pilot symbols. The accumulation time interval can be the duration of the pilot channelization code, an entire pilot reference period, or some other time interval. The samples yᵢ corresponding to pilot symbols are then provided to a pilot filter 410.

Similarly, during non-pilot symbol periods, decover element 532 decovers the despread samples with the particular channelization code used to cover the non-pilot symbols at the remote terminal. The decovered non-pilot samples may be accumulated over a particular time interval by accumulator 534 to generate samples yᵢ, for i=N_{P}+1, . . . , N_{T}, corresponding to non-pilot symbols. The accumulation time interval used for samples corresponding to non-pilot symbols may be the same or different from that used for samples corresponding to pilot symbols. The samples yᵢ corresponding to non-pilot symbols are also provided to pilot filter 410.

Pilot filter 410 may be implemented with any one of the pilot filter designs described above in FIGS. 4A through 4C or some other design. Pilot filter 410 generates pilot estimates based on the samples yᵢ corresponding to pilot and non-pilot symbols and provides the pilot estimates to pilot demodulator 526. Although not shown in FIG. 5, pilot filter 410 may further receive and utilizes the samples for other data symbols (e.g., from symbol accumulator 524) to generate the pilot estimates. Pilot filter 410 typically provides a pilot estimate for each data sample to be demodulated. Depending on the specific implementation, pilot filter 410 may perform interpolation on the FIR or IIR filter output fₖ to generate the required pilot estimates.

Pilot demodulator 526 performs coherent demodulation of the decovered symbols from symbol accumulator 524 with the pilot estimates from pilot filter 536 and provides demodulated symbols to a symbol combiner 540. Coherent demodulation can be achieved by performing a dot product and a cross product of the decovered symbols with the pilot estimates. The dot and cross products effectively perform a phase demodulation of the data and further scale the resultant output by the relative strength of the recovered pilot. The scaling with the pilots effectively weighs the contributions from different multipaths in accordance with the quality of the multipaths for efficient combining. The dot and cross products thus perform the dual role of phase projection and signal weighting that are characteristics of a coherent rake receiver.

Symbol combiner 540 receives and coherently combines the demodulated symbols from all assigned finger processors 510 to provide recovered symbols for a particular received signal being processed by the rake receiver. The recovered symbols for all received signals may then be combined to generate overall recovered symbols that are then provided to the subsequent processing element.

Searcher element 512 can be designed to search for strong multipaths of the received signal at numerous time offsets, and the multipaths having the highest signal quality measurements are selected. The available finger processors 510 are then assigned to process these multipaths.

Pilot energy and noise estimator 550 is implemented to measure pilot energy levels and respective noise estimates of each finger processor.

In the context of fast forward power control, noise estimates form a basis for a decision to change the transmit power at the serving base station. Seeing as incorrect noise estimation resulting from a finger merge condition, introduces a correlation between the data from the two fingers, the preferred embodiment requires noise estimator 550 to account for this correlation in order for fast forward power control to function properly.

Fast Forward Power Control

A short description of fast forward power control will now be described as relates to a CDMA2000 multiple access system which has provisions for fast forward power control. It should be appreciated it however that this description is not intended as all inclusive of only CDMA2000 systems, and that the invention is equally applicable to other systems employing fast forward power control or some variant thereof.

During CMDA2000 fast forward power control, a BS 104 changes the transmit power to a an MS 106 at the rate of 800 Hz. The BS decides to increase or decrease the power of the forward link from the feedback provided by the MS on the reverse link. The MS in its turn forms the feedback decisions for the BS by estimating the received information bit-to-noise ratio (Eb/Nt) on the forward link. This is the so-called inner loop of the power control algorithm. By estimating the received Eb/Nt during a given interval (which is typically 1.25 ms in the cdma2000 forward power control scheme), and feeding the information to the BS, the MS attempts to account for changing channel conditions. The second part of the algorithm, the outer loop, observes the actual frame error rate as seen by the mobile station, and adjusts the Eb/Nt threshold of the inner loop accordingly.

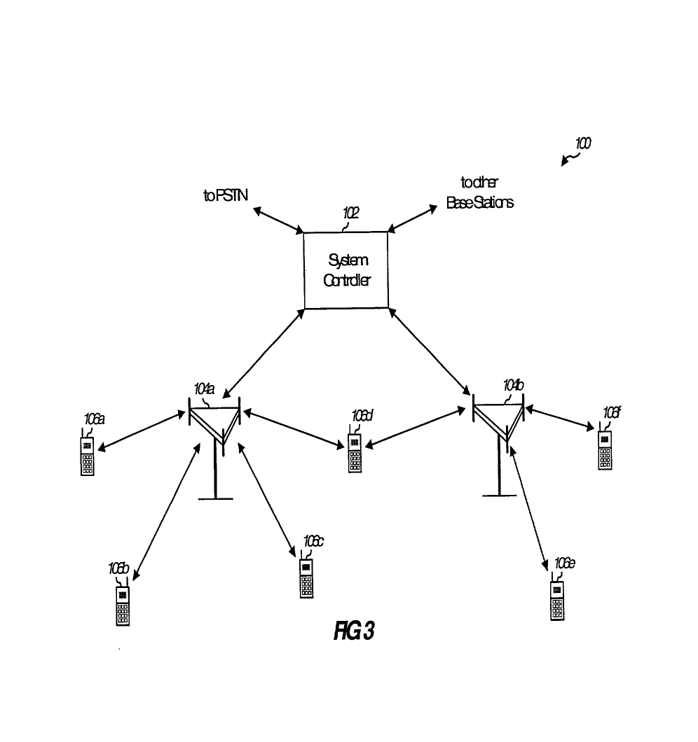

A typical scheme for estimating the received Eb/Nt is to estimate per-finger Eb/Nt, and then combine thus obtained estimates to form an overall Eb/Nt estimate. This was described above in connection with prior art FIG. 2. (Note that in practice Eb and Nt estimates may be formed separately.)

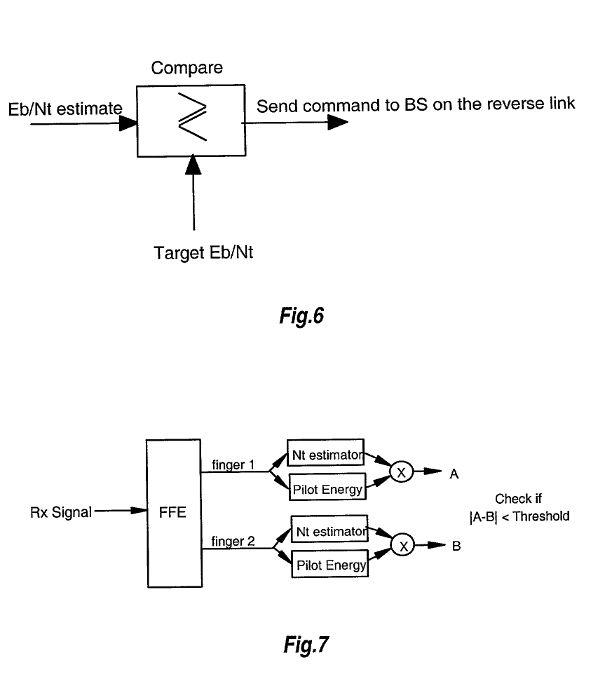

This combined formed estimate is then compared to a threshold, and an up or down command is formed and conveyed to the BS which decides whether to increase or decrease, respectively, the forward link power to the MS. This is illustrated in FIG. 6.

Noise Estimation in Accordance with Invention

As was explained in the background, the noise estimator in a conventional rake receiver architecture (as shown in FIG. 2), assumes that the noise components of each finger are uncorrelated. Therefore in order to obtain an overall noise estimate, it simply adds/combines each noise component that it is contributed by each finger processor. Consequently, during a finger merge (FIG. 1), the noise components are 100% correlated and the noise estimator under-estimates the total noise contribution due to this nonzero cross-correlation between fingers. For the case of a two-finger merge, the noise estimator may under-estimate the true noise level by a factor of 2 in certain cases.

The invention implements a simple, non-computationally intensive noise estimator operation for dealing with the problem of under-estimation resulting from a finger merge condition.

More particularly, in one embodiment, the invention contemplates that the measured noise estimates of each finger processor are compared to actual numbers that are produced by the per-finger Nt estimator derived results. Whenever the numbers from two or more branches (as in the finger merge condition of FIG. 1) become equal or are within a certain delta offset from each other, the noise estimator 550 will declare it as a finger merge condition. Appropriate action would them be taken. This is illustrated in FIGS. 7-10.

In a first embodiment shown in FIG. 7, the noise estimates A, B from different fingers are tested for the condition that either of the numbers falls in a certain neighborhood of each other, i.e., the following satisfied:

|A−B|≦C Equation 1

where C is a positive number.

The purpose of bounding the difference between the noise estimates on the two fingers is to account for possible correlations between finger noises that are less than 100% but greater than 0. This may occur when two fingers are getting close to each other but the complete merge has not occurred yet. Correlations between finger noises will skew overall noise estimate, and will lead to similar effects (but of lesser degree) as in the case of complete finger merge.

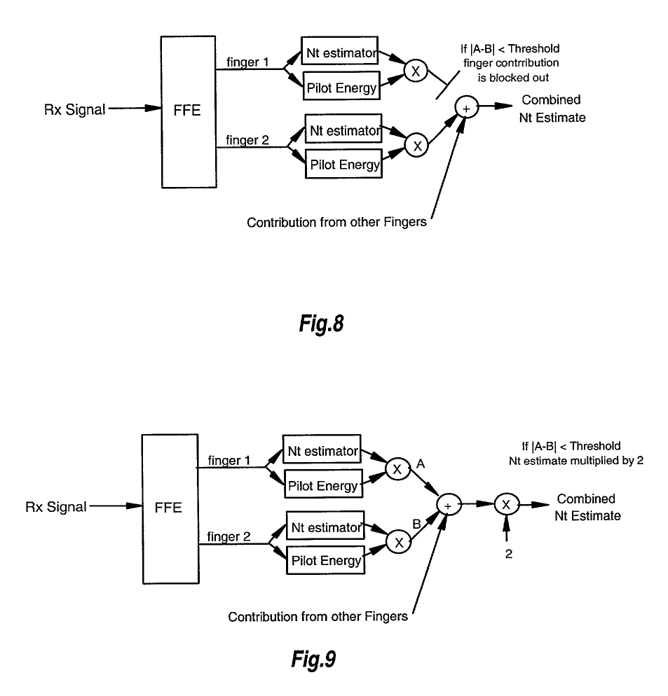

Once the finger merge condition is detected as shown in FIG. 7, an appropriate action may take place. For example, a specific block implemented either in hardware or firmware may block out one finger from contributing to the total Eb/Nt estimate and also to the combined soft decision data entering the deinterleaver/decoder. The scheme showing such blocking (noise component only) is depicted in FIG. 8.

In an alternate embodiment, the combiner may increase the total noise estimate Nt by 3 dB. In this case, only the noise component Nt is corrected. The signal component Eb is estimated as before. This is illustrated in FIG. 9.

The increase of Nt by 3 dB in FIG. 9 is only exemplary. The 3 dB value is valid when two fingers are used to form one Nt estimate. If the number of fingers is larger (as it is usually the case in a typical CDMA rake receiver environment) an actual correcting factor is to be computed based on the total number of fingers and the number of merged fingers.

In spite of the simplicity of this scheme, it still can impose a relatively high computational load because it requires pairwise comparisons of all fingers that form the input to the combiner. When the number of fingers is N, the total number of comparisons is given by the following expression:

$$( \begin{matrix}N \\ 2\end{matrix} ) \qquad \text{Equation 2}$$

which is 6 for N=4 fingers.

In accordance with a further embodiment, a computational procedure is proposed to sort the finger estimates first, and then compare each finger estimate with the estimate of the finger next on the sorted list.

An appropriate sorting algorithm (merge sort, quick sort or bubble sort) may be used for computationally efficient sorting. This will determine all the fingers whose Nt estimate is within a delta offset of all the other fingers. These fingers can be grouped together to identify them as the fingers that merge together.

Further computational improvements may be realized. Due to correlations between consecutive Eb/Nt estimates on each finger, once the fingers are sorted, they are likely to stay so for next few cycles. Therefore, sorting algorithm may be run fewer times, and for the remaining times only a quick check that the fingers remain sorted, is necessary.

While the invention thus far has been described in the context of signal quality estimation, in particular in cdma2000 fast forward power control, it should be appreciated that other operations may also involve noise estimate calculations, and which may or may not deal with estimates where the signal strength and the noise are estimated together, but separately. In addition, while the estimates of the useful signal produced by fingers in the receiver are assumed to be correlated, noise estimates may or may not be correlated depending on relative finger positions.

Summary

The present invention thus proposes a solution to correct noise under-estimation during finger merge conditions. In one scheme, noise under-estimation is corrected when one or more fingers that have merged are blocked from forming the noise estimate. In another scheme a correcting factor is introduced to account for the correlation between noise estimates from merged fingers.

Furthermore, a computationally effective procedure is described to perform such comparisons between the noise estimates from individual fingers by sorting noise estimates according to their magnitude first, and then comparing only samples that are neighbors in the sorted list.

Furthermore, any such sorting may be performed only from time to time, while at other times only checking that fingers remain sorted is required.

In particular, due to correlations between consecutive Nt estimates, the noise estimator of the present invention may first perform checking to determined whether the fingers are sorted; and if they are not, the algorithm may compute “dis-sorting” distance, i.e., an estimate of the degree to which fingers have become un-sorted.

For example, suppose there are 4 fingers and the sorting order is 4, 3, 1, 2. Suppose that at a certain cycle the new sorting order is 4, 3, 2, 1. Then the sorting algorithm will detect first that the old sorting order 4, 3, 1, 2 is no longer valid, then will determine that the violation of the sorting order has happened in the last two fingers only, and thirdly, will swap the last two fingers to restore the sorting order, i.e., the final result of running the sorting algorithm will have all fingers sorted in the correct order—4, 3, 2, 1.

Noise estimator efficiency may further be improved. In particular, whenever the higher-level software performs the finger assignment, it can also pre-sort the fingers for the lower-level sorting algorithm described above in connection with the sorting operation described previously. Once accomplished, the control over maintaining fingers in a sorted order (and taking an appropriate corrective action in the case of merged fingers) between the assignment cycles is passed to the noise estimator algorithm.

For simplicity, various aspects and embodiments of an improved noise estimator in a rake receiver architecture have been described for a specific implementation in a mobile station of a CDMA system. The noise estimation techniques may also be implemented and used in the base station terminal of the CDMA system.

The noise estimation techniques relevant to finger merge described herein may be implemented in hardware, software, firmware, or a combination thereof. For a hardware design, the noise estimator operation may be implemented within a digital signal processor (DSP), an application specific integrated circuit (ASIC), a processor, a microprocessor, a controller, a microcontroller, a field programmable gate array (FPGA), a programmable logic device, other electronic unit, or any combination thereof. And for a software or firmware design, the noise estimat or operation may be implemented with codes executed by a processor (e.g., controller 230 or 270 in FIG. 2).

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

1. A method of noise estimation during a finger merge condition, comprising:
determining noise estimates from a plurality of finger processors;
comparing the noise estimates to determine if they are at least within a certain delta offset of each other; and
before combining noise estimates, taking a corrective action to prevent noise under-estimation.

2. The method of claim 1, wherein taking a corrective action involves blocking the noise estimate from being included in a combined noise estimate total.

3. The method of claim 2, wherein the combined noise estimate total forms the basis of a fast forward power control decision.

4. The method of claim 2, further comprising sorting the noise estimates before comparing.

5. The method of claim 4, further comprising determining whether the noise estimates are sorted.

6. The method of claim 4, further comprising determining a dis-sorting distance before performing the sorting.

7. The method of claim 1, wherein taking a corrective action involves applying a correction factor to a combined total noise estimate.

8. The method of claim 7, wherein the combined noise estimate total forms the basis of a fast forward power control decision.

9. The method of claim 7, further comprising sorting the noise estimates before comparing.

10. The method of claim 9, further comprising determining whether the noise estimates are sorted.

11. The method of claim 9, further comprising determining a dis-sorting distance before performing the sorting.

12. A noise estimator for improving signal quality estimation during a finger merge condition, comprising:
means for determining noise estimates from a plurality of finger processors;
means for comparing the noise estimates to determine if they are at least within a certain delta offset of each other; and
means for taking a corrective action, before combining noise estimates, to prevent noise under-estimation.

13. The noise estimator of claim 12, wherein the means for taking a corrective action involves blocking the noise estimate from being included in a combined noise estimate total.

14. The noise estimator of claim 13, wherein the combined noise estimate total forms the basis of a fast forward power control decision.

15. The noise estimator of claim 13, further comprising means for sorting the noise estimates before comparing.

16. The noise estimator of claim 15, further comprising before means for determining whether the noise estimates are sorted.

17. The noise estimator of claim 15, further comprising means for determining a dis-sorting distance before performing the sorting.

18. The noise estimator of claim 12, wherein taking a corrective action involves applying a correction factor to a combined total noise estimate.

19. The noise estimator of claim 18, wherein the combined noise estimate total forms the basis of a fast forward power control decision.

20. The noise estimator of claim 18, further comprising means for sorting the noise estimates before comparing.

21. The noise estimator of claim 20, further comprising means for determining whether the noise estimates are sorted.

22. The noise estimator of claim 20, further comprising means for determining a dis-sorting distance before performing the sorting.
